(19) United States
(12) Patent Application Publication
(10) Pub. No.: US 2009/0218563 A1
(43) Pub. Date: Sep. 3, 2009

(54) NOVEL FABRICATION OF SEMICONDUCTOR QUANTUM WELL HETEROSTRUCTURE DEVICES

(76) Inventors: Bruce Alvin Gurney, San Jose, CA (US); Ernesto E. Marinero, Saratoga, CA (US)

Correspondence Address: ZILKA-KOTAB, PC- HIT, P.O. BOX 721120, SAN JOSE, CA, 95172-1120, US

(21) Appl. No.: 12/039,594

(22) Filed: Feb. 28, 2008

(51) Int. Cl. H01L 29/12; H01L 21/338

(52) U.S. Cl. 257/24; 438/172; 257/E29.069; 257/E21.403

(57) ABSTRACT

A device employing a quantum well structure having a pattern that is defined by a photolithographically patterned top gate electrode. By defining the active area of the quantum well structure by the patterning of the top gate electrode there is no need to pattern the quantum well structure itself, such as by etching or other processes. This advantageously allows the active are of the quantum well structure to be patterned to a very small size, without the damaging edge effects associated with the patterning of the quantum well structure itself.

### FIELD OF THE INVENTION

The present invention relates generally to devices employing quantum well structures, and more particularly to the remote patterning of said quantum well structures, to define the electron (hole) channel lateral dimensions without the need to pattern or etch the semiconductor heterostructure comprising said quantum well.

### BACKGROUND OF THE INVENTION

Devices based on quantum well structures employing III-V semiconductors have significantly impacted the development of ultra-fast transistors, high sensitivity optical and magnetic sensors, and have permitted the development of quantum cascade lasers and Tera Hertz (THz) sources. Of particular importance and challenge is the need to fabricate quantum well heterostructure devices with nano-scale dimensions. State-of-the art fabrication methods, including electron-beam and atomic force microscopy lithography are hindered in achieving the smallest possible features by undesirable effects at the edges and surfaces of the patterned heterostructures, which negatively impact their transport characteristics. This includes, surface states, dangling bonds, band structure modifications and the introduction of roughness and defects at the walls of the device. Surface edge effects reduce the carrier mobility through increased carrier scattering processes and result in lack of control of the channel electron (hole) density and/or lead to the introduction of secondary conduction channels. Thereby limiting the ultimate channel width attainable in such devices.

One method that has been considered to construct quantum well nano-structures has been described by Yang et al. in U.S. Pat. No. 6,703,639. This patent teaches the use of an etched capping layer to define a pattern of a quantum well structure. As taught by Yang, a doped layer and a capping layer are formed over the quantum well structure. Desired portions of the capping layer are then removed by etching, and the etched regions define a pattern of the quantum well structure. Such a device requires physical removal of a portion of the heterostructure (e.g. the capping layer) by etching in order to define the quantum well structure.

### SUMMARY OF THE INVENTION

The present invention provides structure including a semiconductor heterostructure defining a quantum well structure, the quantum well structure having an active area. A patterned electrode is formed over the heterostructure such that an active regions of the quantum well structure is defined by the patterned electrode.

A device according to the invention can form a quantum well structure having a pattern that is defined by a photolithographically patterned top gate electrode. By defining the active area of the quantum well structure by the patterning of the top gate electrode there is no need to pattern the quantum well structure itself, such as by etching or other processes. This advantageously allows the active area of the quantum well structure to be patterned to a very small size, without the damaging edge effects associated with the patterning of the quantum well structure itself.

These and other features and advantages of the invention will be apparent upon reading of the following detailed description of preferred embodiments taken in conjunction with the Figures in which like reference numerals indicate like elements throughout.

### BRIEF DESCRIPTION OF THE DRAWINGS

For a fuller understanding of the nature and advantages of this invention, as well as the preferred mode of use, reference should be made to the following detailed description read in conjunction with the accompanying drawings which are not to scale.

FIG. 1 is a schematic illustration of a prior-art Lorentz Magnetoresistive device in which the invention might be embodied

FIG. 2 is a cross sectional, top-down view taken from line 2-2 of FIG. 1;

FIG. 3 is a side cross sectional view of a portion of a device according to an embodiment of the invention;

FIG. 4 is a top down view as viewed from line 4-4 of FIG. 3;

FIG. 5 is a side, cross sectional view according to an embodiment of the invention; and

FIG. 6 is a side cross sectional view according to another embodiment of the invention.

### DETAILED DESCRIPTION OF THE PREFERRED EMBODIMENTS

The following description is of the best embodiments presently contemplated for carrying out this invention. This description is made for the purpose of illustrating the general principles of this invention and is not meant to limit the inventive concepts claimed herein.

The present invention provides a mechanism for defining the active area of a device employing a quantum well structure without the need to physically pattern the semiconductor heterostructure comprising the quantum well structure itself, such as is done in mesa formation of semiconductor heterostructures. This, therefore, avoids the inherent damage caused by fabrication techniques such as reactive ion etching (RIB), ion milling, and chemical etching.

A quantum well structure can be in the form of a two dimensional electron gas (2DEG) or two dimensional hole gas. Such quantum well structures show promise for use as very small narrow and short electron (hole) channels which can be used as nano-wires in nano-scale circuitry electronics or nanosensors in sensor technology. As mentioned above, quantum well structures may be used in the development of ultra-fast transistors, high sensitivity optical and magnetic sensors, and have permitted the development of quantum cascade lasers and THz sources. These are however, only examples of the many possible applications of quantum well structures.

One area in which quantum well structures show particular promise is in the area of magnetoresistive sensors. Magnetoresistive sensors, such as those based on the Hall effect show promise in producing magnetoresistive sensors that can be used, for example, in magnetic data recording systems, for very high data density recording. Although the invention is not limited to use in magnetoresistive sensing nor in magnetic data storage, the invention can be better understood by describing the advantage of such an invention as implemented in a magnetoresistive sensor.

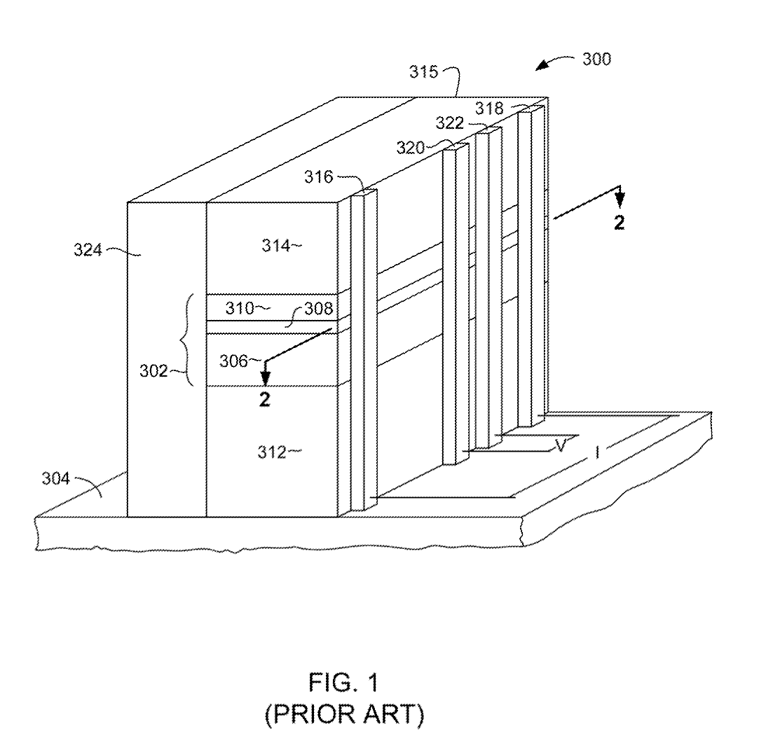

With reference then to FIG. 1, a prior art extraordinary magnetoresistive sensor (EMR) 300 is described as one possible example of a device that can employ a quantum well. This is, however, only an example of a structure employing a quantum well structure. Quantum well structure can be used in many other applications and devices. The EMR sensor 300 may include a structure 302 that is a III-V heterostructure formed on a semiconductor substrate 304 such as GaAs or Si. However, the EMR sensor described in this invention need not be restricted to III-V semiconductor materials. For example, it may also be formed on the basis of silicon, or germanium. The heterostructure 302 includes a first layer 306 of semi-conducting material having a first band-gap, a second layer 308 of semi-conducting material formed on the first layer 306 and having a second band-gap that is smaller than that of the first layer 306, and a third semi-conducting layer 310 of semi-conducting material formed on top of the second layer 308 and having a third band gap that is greater than the second band gap. The materials in the first and third layers 306, 310 may be similar or identical. An energetic potential well (quantum well) is created by the first, second and third semi-conducting material layers due to the different band-gaps of the different materials. Thus, carriers can be confined inside layer 308, which is considered the EMR active film in the sensor 300. This is also referred to as the quantum well or a two-dimensional electron gas (2DEG) layer.

The first layer 306 is typically formed on top of a buffer layer 312 that may be one or more layers. The buffer layer 312 comprises several periods of a superlattice structure that functions to prevent impurities present in the substrate from migrating into the functional layers 306, 308, 310. In addition, the buffer layer 312 is chosen to accommodate the typically different lattice constants of the substrate 304 and the functional layers of the heterostructure 302 to thus act as a strain, relief layer between the substrate and the functional layers.

One or more doped layers are incorporated into the semiconducting material in the first layer 306, the third layer 310, or both layers 306 and 310, and spaced apart from the boundary of the second and third semiconducting materials. The doped layers provide electrons (if n-doped) or holes (if p-doped) to the quantum well. The electrons or holes are concentrated in the quantum well in the form of a two dimensional electron-gas or hole-gas, respectively. Doping layers are not necessary in the case of AlSb/InAs/AlSb heterostructures wherein the electrons originate from deep donors in the AlSb layers as well as from states at the interface between the AlSb and the InAs quantum well.

The layers 306, 308, 310 may be a Al_{0.09}In_{0.91}Sb/InSb/Al_{0.09}In_{0.91}Sb heterostructure grown onto a semi-insulating GaAs substrate 304 with a buffer layer 312 in between. The layers 306, 308, 310 may also be AlSb/InAs/AlSb. InSb, GaAs and InAs are narrow band-gap semiconductors. Narrow band-gap semiconductors typically have a high electron mobility, since the effective electron mass is greatly reduced. For example, the room temperature electron mobility of InSb and InAs are 70,000 cm²/Vs and 35,000 cm²/Vs, respectively.

The bottom Al_{0.09}In_{0.91}Sb layer 306 formed on the buffer layer 312 has a thickness in the range of approximately 1-3 microns and the top Al_{0.09}In_{0.91}Sb layer 310 has a thickness in the range of approximately 10 to 1000 nm, typically 20 cm. The doping layers incorporated into layers 306, 310 have a thickness from one monolayer (delta-doped layer) up to 10 nm. The doping layer is spaced from the InSb/Al_{0.09}In_{0.91}Sb boundaries of first and second or second and third semi-conducting materials by a distance of 10-300 Angstrom. n-doping is preferred, since electrons typically have higher mobility than holes. The typical n-dopant is silicon with a concentration in the range of 1 to 10¹⁹/cm³. In the case of AlSb/InAs/AlSb quantum wells, delta doping is also possible to increment the electron density in the InAs quantum well. This is typically done by intercalating a few monolayers of Te within the AlSb layers. The deposition process for the heterostructure 302 is preferably molecular-beam-epitaxy, but other epitaxial growth methods can be used.

A capping layer 314 is formed over the heterostructure 302 to protect the device from corrosion. The capping layer 314 is formed of an insulating material such as oxides or nitrides of aluminum or silicon (e.g., Al₂O_{3,}Si₃N₄,) or a non-corrosive semi-insulating semiconductor. The layers 312, 306, 308, 310, 314 together form a structure that can be referred to as a mesa structure 315.

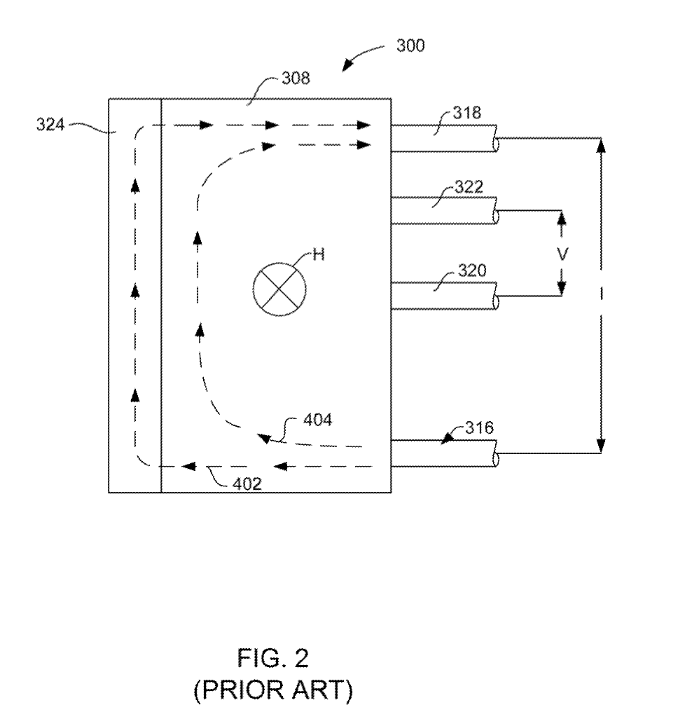

Two current leads 316, 318 and two voltage leads 320, 322 are patterned over one side of the EMR structure 302 so that they make electrical contact with the quantum well. A metallic shunt 324 is patterned on the side opposite the current and voltage leads of the EMR structure 302 so that It makes electrical contact with the quantum well. An applied magnetic field H (FIG. 2), i.e., the magnetic field to be sensed, is generally oriented normal to the plane of the layers in the EMR structure 302. The leads typically comprise metallic contacts, for example An, AuGe, or Ge diffused into the device. For the case of an EMR device based on Si, the leads and shunt material are preferably a metallic alloy of Si, such as TiSi₂, or regions of highly n-type doping. The leads are typically formed after deposition of the capping layer 314, and sometimes after removal of some of the capping layer material.

FIG. 2 is a top-down schematic view of the EMR sensor 300 through a section of the active film 308 and will illustrate the basic operation of the sensor. In the absence of an applied magnetic field H, sense current through the leads 316, 318 passes into the semiconductor active film 308 and is shunted through the shunt 324, as shown by line 402. When an applied magnetic field H, having a component perpendicular to the plane of the layers in the EMR structure 302, is present, as shown by the arrow tail into the paper in FIG. 2, current is deflected from the shunt 324 and passes primarily through the semiconductor active film 308, as shown by line 404. The change in electrical resistance due to the applied magnetic field is detected across the voltage leads 320, 322.

Construction of a device having a mesa structure 315, such as that described above with reference to FIG. 1, presents certain manufacturing and design challenges. The very act of forming the mesa structure 315 to define the active configuration of the quantum well structure 308 damages the quantum well structure 308. These challenges become more acute as the size of the device becomes smaller, such as in devices having nano-scale dimensions. State-of-the-art fabrication methods, including electron-beam and atomic force microscopy lithography are hindered in achieving the smallest possible features by undesirable effects at the edges and surface of the mesa structure, which negatively affect the transport characteristics of the active layer 308. This includes surface states effects, dangling bonds, band structure modifications and the introduction of roughness and defects at the walls of the mesa structure 315. These surface and edge effects reduce the carrier mobility through increased scattering phenomena and result in lack of control of the channel electron (or hole) density in the active layer, as well as the introduction of secondary conduction channels.

What is needed is a fabrication approach that defines the active areas of the device employing a quantum well structure without the need to physically pattern the quantum well channel in the semiconductor heterostructure, thereby avoiding the inherent damage induced by fabrication techniques that require material removal such as reactive ion etching and chemical etching.

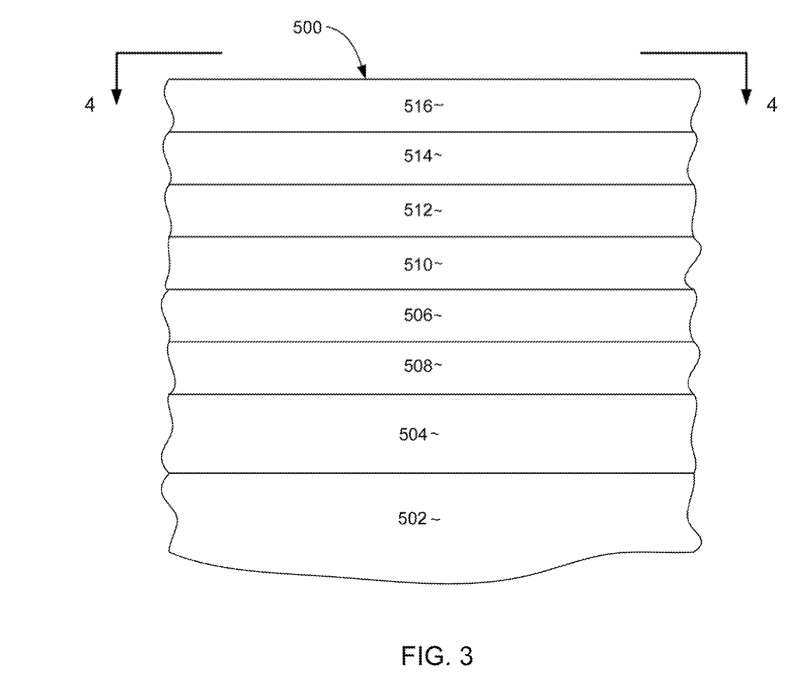

The present invention provides a method and structure for defining an active region of a quantum well device through a lithographically patterned metal electrode formed either above or beneath the active layer of the device as will be seen below. With reference now to FIG. 3, a view of device 500 employing a quantum well structure is shown in cross section. The device 500 can be formed upon a substrate 502 that can be, for example, semiconductor wafer such as a GaAs or Si. A buffer layer 504 may be formed over the substrate 502. In the case of a Si substrate, additional layers of SiGe are needed to accommodate the lattice mismatch between Si and III-V based layers. The buffer layer 504 can be constructed as several periods of a superlattice structure that functions to prevent impurities present in the substrate from migrating into the above layers.

The device 500 also includes an active layer 506 sandwiched between first and second liner layers 508, 510. The active layer 506 and liner layers 508, 510 are chosen such that active layer 506 forms a quantum well. This can be in the form of a two dimensional electron gas (2DEG) or can be a two dimensional hole gas if the charge carriers are to be holes. The active layer 506 can be constructed of, for example, InAs, and the liner layers 508, 510 can each be constructed of, for example, AlSb.

With continued reference to FIG. 3, a doped layer or multilayer 512 is provided above the liner layer 510. The doped layer 512 can be a p-doped layer of InAs, but can be other materials as well depending upon the makeup of the layers 504, 506 below. If the quantum well structure is a 2DEG constructed of InAs, then the doped layer can be, for example, p-doped InAs. An oxide layer 514 is then formed over the doped layer 512, and an electrically conductive top-gate electrode 516 can be formed over the oxide layer 514. The oxide layer is preferred to avoid voltage leakage from the gating electrode but depending on the nature of the electrical resistance and contact between the gating electrode and the p-dope layer 512, it can be dispensed with.

As deposited, the layers 502-512, cause the active layer 506 to be an electrical insulator or a very poor conductor. On account of the fact that there are no 2D electrons in the quantum well by virtue of the compensation effected by the p-doped overlayers. However, when a bias voltage of the correct magnitude is applied between the gate electrode 516 and the substrate 502, or another counter-electrode buried layer in the stack, the electrostatic potential necessary to achieve transport in the quantum well is provided. This is on account of the field-induced Fermi level shift required to introduce donor carriers into the active layer 506, causing the active layer 506 to form (in this case) a two dimensional electron gas. As mentioned above, the invention is also applicable to a structure wherein the active layer 506 provides a two dimensional hole gas. Therefore, the active layer 506 is active only in regions where the top gate electrode 516 is present and is supplied with a bias potential. In regions where the top-gate electrode 516 is not present, the active layer 506 is an insulator.

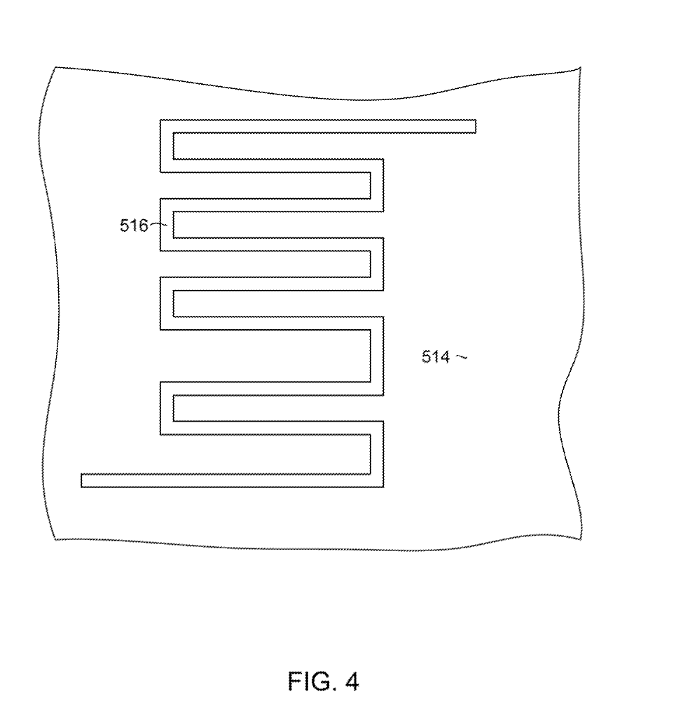

Therefore, with reference to FIG. 4, which shows a top down view, it can be seen that the top-gate electrode 516 has been photolithographically patterned to define a desired active area for the active layer 506 (FIG. 3). As discussed above, regions of the active layer 506 over which the top-gate electrode 516 extends will be active, whereas areas not covered by the top-gate electrode 516 will act as an electrical insulator. The pattern defined by the electrode 516 could be any desired pattern such as the formation of a nano-electronic device or a section thereof such as nano-wire or some other device. The pattern shown in 4 is merely for purposes of illustration. The resulting patterned active area can be any of various possible forms of circuitry. In essence, the invention provides a means of forming a nano-wire or for forming extremely small circuitry, wherein the pattern of the circuitry is defined by the pattern of the top gate electrode rather than by physical patterning of the quantum well structure.

As mentioned above, the top-gate electrode 516 can be photolithographically patterned. This could be achieved by, for example, by forming a photoresist mask (not shown) having an opening that is configured to define the shape of the top gate electrode 516 as shown in FIG. 4. An electrically conductive material, can then be deposited, such as by sputtering, and then the mask can be lifted off. Alternatively, the top-gate electrode material can be deposited full trim, such as by sputter deposition or some other suitable method, and then a mask can be formed to cover an area that defines the top-gate electrode 516. A material removal process such as ion milling, reactive ion etching or chemical etching can then be used to remove portions of the top gate electrode material that are protected by the mask. The mask can then be lifted off, leaving a structure such as that shown in FIG. 4.

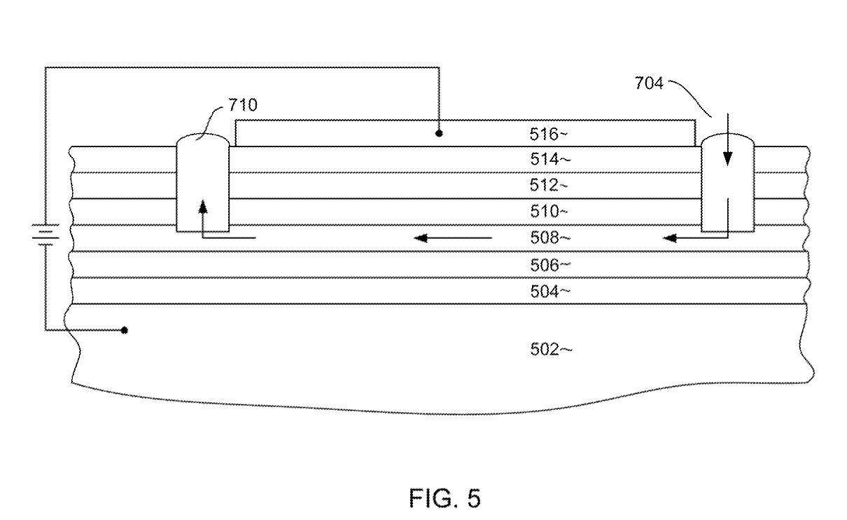

With reference now to FIG. 5 an etching process can be performed to etch into the layers 516, 514, 512 510, to form one or more openings to make contact with selected portions of the active layer 506 of the quantum well structure. An electrically conductive material can then be deposited into these openings to form contact studs 704, 710, which make contact with the contact active region a shown in FIG. 8. This electrical contact with the quantum well structure can be made outside of a critical, active region of the device.

While the top-gate electrode 516 can be a metal, it can also be constructed of graphene. Graphene is a single atomic sheet of graphitic carbon atoms that are arranged in to a honeycomb lattice. It can be viewed as a single, giant two-dimensional fullerene molecule, an unrolled single wall carbon nano-tube, or simply a single layer of lamellar graphite crystal. Interest in graphene was triggered by its discovery as cited in (Novoselov, K. S. et al, Science 306, 666, 2004; Proc. Natl Acad. Sci., USA 102, 10451, 2005. It is a stable and mechanically robust zero-gap semiconductor that displays ballistic electron properties. In the case of a magnetoresistive sensor such as an extraordinary magnetoresistive sensor, constructing the top gate electrode 516 of graphene provides the advantage of allowing the quantum well structure to be as close as possible to the surface of the device. Sensor response drops off exponentially with increased distance from the source of the magnetic field (e.g. the magnetic medium). Therefore, reducing the spacing between the active portion of the quantum well structure 506 and the surface of the device greatly enhances the performance of the device. Since a graphene electrode 516 has the thickness of only a single carbon atom, the thickness of the top gate electrode is negligible.

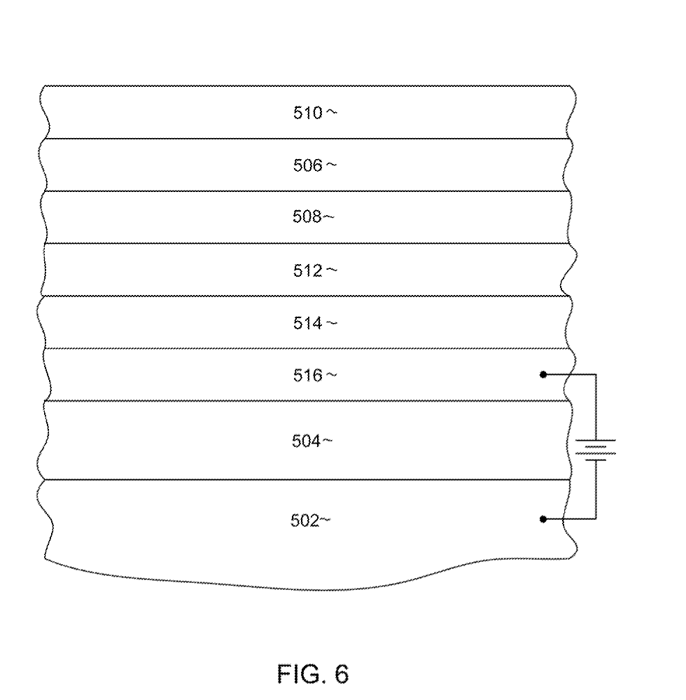

With reference now to FIG. 6, in another embodiment of the invention 900, the patterned electrode 516 is generated prior to the deposition of the quantum well structure so that it is beneath the quantum well structure 512. The quantum well 512 as deposited is an electrical insulator. When a voltage is applied the between the patterned electrode and the substrate, the resulting electric field shifts the surface Fermi Level leading to the presence of charge carriers in the quantum well channel 512 in areas directly above the patterned electrode 516. This embodiment, while possibly more difficult to construct can provide the advantage, when used in a magnetoresisitive sensor, that the quantum well structure 512 is closer to the surface, and therefore, closer to the source of a magnetic field to be detected. However, it should be pointed out again that the invention is by no means limited to magnetoresistive sensors.

As discussed above, the invention allows the construction of nano-scale quantum well structures such as nano-wires, which can be used in the construction of ultrafast transistors, high sensitivity optical and magnetic sensors, quantum cascade lasers and Tera-Hertz sources. Performance enhancements of such devices include: sustained mobilities (as for macroscopic devices); longer coherence lengths (to facilitate quantum interference devices); and wave-guide devices where the specular reflection at the channel walls enables realization of wave-optics based solid state analogues. The above described invention can be used in the construction of any of various forms of mesoscopic devices.

The above described invention avoids etching any of the layers of the quantum well structure, including etching of the capping layer. Therefore, no topological changes concomitant with edge effects are introduced. An advantage derived from the invention is that by simply changing the magnitude of the bias voltage applied to the top gate electrode, one can continuously tune and control the desired magnitude of band bending. This is not possible with prior art structures or methods that rely on the discrete energy gap difference between lattice matched wide and narrow band gap semiconductors. The invention is also readily extendible to quantum wells employing holes as the transport carriers. In addition, the electrode can be extremely thin so that one can employ a variety of lithographic patterning techniques to generate ultra-smooth edges in the electrode to better control the vertical profile of the electrostatic field that defines the active quantum well channel beneath the top-gate electrode.

While various embodiments have been described above, it should be understood that they have been presented by way of example only, and not limitation. Other embodiments failing within the scope of the invention may also become apparent to those skilled in the art. Thus, the breadth and scope of the invention should not be limited by any of the above-described exemplary embodiments, but should be defined only in accordance with the following claims and their equivalents.

What is claimed is:

1. An apparatus, comprising:
a semiconductor heterostructure defining a quantum well structure, the quantum well structure having an active area,
a patterned electrode, wherein the active regions of the quantum well structure is
defined by the patterned electrode and
a lead for applying a gate voltage to the patterned electrode to permit carrier transport in the quantum well.

2. An apparatus as in claim 1 further comprising an oxide layer disposed between the patterned electrode and the quantum well structure, the oxide layer forming a tunneling barrier.

3. An apparatus as in claim 1 further comprising a doped layer disposed between the quantum well structure and the patterned electrode.

4. An apparatus as in claim 3 wherein the doped layer is a p-doped layer and the charge carriers in the quantum well are electrons.

5. An apparatus as in claim 3 wherein the doped layer is a n-doped layer and the charge carriers in the quantum well are holes.

6. An apparatus as in claim 1 further comprising:
a doped layer disposed between the quantum well structure and the patterned electrode; and
an oxide layer disposed between the doped layer and the patterned electrode, the patterned electrode forming a tunneling barrier.

7. An apparatus as in claim 1 wherein the active area of the quantum well structure defines a two dimensional electron gas.

8. An apparatus as in claim 1 wherein the active area of the quantum well structure defines a two dimensional hole gas.

9. An apparatus as in claim 1 wherein the quantum well structure is sandwiched between first and second liner layers.

10. An apparatus as in claim 1 wherein the patterned electrode comprises a metal.

11. An apparatus as in claim 1 wherein the patterned electrode comprises graphene.

12. An apparatus as in claim 1 wherein the patterned electrode is formed above the quantum well structure.

13. An apparatus as in claim 1 wherein the patterned electrode is buried beneath the quantum well structure.

14. An apparatus as in claim 1 wherein the quantum well structure further comprises a layer of InAs sandwiched between first and second layers of AlSb.

15. An apparatus as in claim 1 wherein the quantum well structure further comprises a layer of InAs sandwiched between first and second layers of AlSb, the apparatus further comprising:
a p-doped layer of InAs disposed between the quantum well structure and the patterned electrode; and
an oxide layer disposed between the p-doped layer of InAs and the patterned electrode.

16. An apparatus as in claim 14 wherein the patterned electrode comprises graphene.

17. An apparatus as in claim 1 wherein the apparatus is a magnetoresistive sensor

18. An apparatus as in claim 1 wherein the apparatus is a magnetoresisitive sensor and further comprises a plurality of leads, electrically connected with a first side of the active area of the quantum well structure and an electrically conductive shunt structure electrically connected with a second side of the active area of the quantum well structure.

19. An apparatus as in claim 1 wherein the apparatus is embodied in a transistor.

20. An apparatus as in claim 1 wherein the apparatus is embodied in an optical sensor.

21. An apparatus as in claim 1 wherein the apparatus is embodied in a quantum cascade laser.

22. An apparatus as in claim 1 wherein the apparatus is embodied in a Tera-Hertz source.

23. An apparatus as in claim 1 wherein the quantum well structure exhibits sustained carrier mobility due to an absence of edge effects.

24. An apparatus as in claim 1 wherein the quantum well structure exhibits a long coherence length.

25. A method for manufacturing a an electronic device, comprising:
forming a quantum well structure;
forming an electrode;
forming a doped layer between the quantum well structure and the electrode; and
patterning the electrode to define an active area of the quantum well structure.
